(19) United States
(12) Patent Application Publication
(10) Pub. No.: US 2026/0143794 A1
(43) Pub. Date: May 21, 2026

(54) INTEGRATED CIRCUIT DEVICES INCLUDING STACKED TRANSISTORS WITH EXTENDED CELL HEIGHTS

(71) Applicant: Samsung Electronics Co., Ltd., Suwon-si (KR)

(72) Inventors: Young Gook Park, Rensselaer, NY (US); Hyo Jong Shin, Mechanicville, NY (US); Jinyoung Lim, Schenectady, NY (US); Kang-ill Seo, Springfield, VA (US)

(21) Appl. No.: 19/332,581

(22) Filed: Sep. 18, 2025

Related U.S. Application Data
(60) Provisional application No. 63/722,314, filed on Nov. 19, 2024.

(51) Int. Cl. H10D 84/83; H01L 23/528; H10D 30/00; H10D 30/43; H10D 62/10

(52) U.S. Cl. CPC H10D 84/8311; H10D 30/43; H10D 30/502; H10D 62/121; H10D 84/8312; H10D 84/832; H10W 20/435

(57) ABSTRACT

An integrated circuit device may include a substrate and a cell structure on an upper surface of the substrate. The cell structure may comprise at least a portion of a first transistor that comprises a first sidewall and a second sidewall that is opposite to the first sidewall and at least a portion of a second transistor that comprises a third sidewall and a fourth sidewall that is opposite to the third sidewall between the upper surface of the substrate and the first transistor. One of the third sidewall and the fourth sidewall may overlap the first transistor. The at least the portion of the first transistor may have a first cell width. The at least the portion of the second transistor may have a second cell width. The first cell width may be different from the second cell width.

### CROSS-REFERENCE TO RELATED APPLICATIONS

The present application claims the benefit of U.S. Provisional Patent Application Ser. No. 63/722,314, filed on Nov. 19, 2024, entitled TRANSISTOR STRUCTURE FORMED ACROSS-CELL BOUNDARY, the disclosure of which is hereby incorporated herein in its entirety by reference.

### BACKGROUND

The present disclosure generally relates to the field of integrated circuit devices and, more particularly, to integrated circuit devices including stacked transistors.

Various structures of an integrated circuit device and methods of forming the same have been proposed to increase the integration degree. For example, a stacked transistor structure including multiple transistors vertically stacked has been proposed.

The stacked transistor structure may be in an I-shape scheme or an L-shape scheme in a cross-sectional view. In the I-shape scheme, an upper transistor and a lower transistor may have (substantially) the same size (e.g., (substantially) the same cell height or (substantially) the same channel width) and may be aligned with each other in a horizontal direction. In the L-shape scheme, an upper transistor and a lower transistor may have different sizes (e.g., different cell heights or different channel widths) from each other. In the L-shape scheme, one of sidewalls of the upper transistor and one of sidewalls of the lower transistor may be aligned in a horizontal direction.

In the I-shape scheme and the L-shape scheme, a middle-of-line (MOL) structure spaced apart from the upper transistor and/or the lower transistor in a horizontal direction may be needed to provide connectivity (e.g., electrical connectivity) among front-side conductive tracks (e.g., front-side power delivery network and/or front-side signal tracks on an upper surface of the upper transistor), back-side conductive tracks (e.g., back-side power delivery network and/or back-side signal tracks on a lower surface of the lower transistor), the upper transistor, and the lower transistor because the upper transistor and the lower transistor substantially or completely overlap with each other in the vertical direction and may not have enough space on which the front-side conductive tracks and the back-side conductive tracks land through conductive contacts and/or conductive vias in the vertical direction. In summary, the I-shape scheme and the L-shape scheme may need extra space for the MOL structure adjacent the upper transistor and/or the lower transistor (e.g., between the transistor(s) and a cell boundary), and therefore, the overall footprint of the integrated circuit device may increase, and the integration degree of the integrated circuit device may be limited.

### SUMMARY

An aspect of the present disclosure is to provide a Z-shape scheme for a stacked transistor structure. In the Z-shape scheme, the upper transistor and the lower transistor may be staggered with respect to each other (in a horizontal direction). In other words, the upper transistor and the lower transistor in the Z-shape scheme may be positioned in a zigzag arrangement.

In the Z-shape scheme, the MOL structure may be positioned to be (completely) overlapped by the upper transistor and/or the lower transistor in the vertical direction because the upper transistor and the lower transistor have less overlap with each other in the vertical direction. In other words, the MOL structure may be provided in the areas overlapping the upper transistor and/or the lower transistor in the vertical direction rather than in the areas adjacent (sidewalls of) the upper transistor and/or the lower transistor. As a result, the front-side conductive tracks and back-side conductive tracks may be electrically connected to the upper transistor and the lower transistor without a detour (e.g., a detour through the areas between the transistors and a cell boundary), and the integration degree of the integrated circuit may increase.

Since the MOL structure is not located in the areas adjacent the cell boundary, such areas may be utilized for the performance improvement of the integrated circuit device. For example, the transistor (e.g., the upper transistor and/or the lower transistor) may extend further into the areas adjacent the cell boundary (from which the MOL structure is removed). The extension of the transistor into the areas adjacent the cell boundary may provide design flexibility. For example, when the upper transistor and the lower transistor are different types of transistors (e.g., P-type transistor and N-type transistor), the sizes of the transistors (e.g., cell heights and/or channel widths) may be adjusted (e.g., maximized) for the controlling and synchronizing the input/output (I/O) timings of the transistors or other special purposes (e.g., switch cells) by utilizing the areas adjacent the cell boundary.

An aspect of the present disclosure is to provide integrated circuit devices with improved flexibility and availability of the areas adjacent the cell boundary. However, it will be understood that the embodiments, goals, and benefits of the present disclosure are not limited to the descriptions above.

An integrated circuit device, according to some embodiments, may include a substrate and a cell structure on an upper surface of the substrate. The cell structure may comprise at least a portion of a first transistor that comprises a first sidewall and a second sidewall that is opposite to the first sidewall in a first direction that is parallel with the upper surface of the substrate and at least a portion of a second transistor that comprises a third sidewall and a fourth sidewall that is opposite to the third sidewall in the first direction between the upper surface of the substrate and the first transistor in a second direction that is perpendicular to the upper surface of the substrate. One of the third sidewall and the fourth sidewall may overlap the first transistor in the second direction. The at least the portion of the first transistor may have a first cell width in the first direction. The at least the portion of the second transistor may have a second cell width in the first direction. The first cell width may be different from the second cell width.

An integrated circuit device, according to some embodiments, may include a substrate, a first cell structure on an upper surface of the substrate, a second cell structure that is adjacent the first cell structure in a first direction that is parallel with the upper surface of the substrate, a cell boundary between the first cell structure and the second cell structure in the first direction, a first transistor crossing the cell boundary in the first direction and extending into the first cell structure and the second cell structure, and a second transistor in at least one of the first cell structure and the second cell structure. The first transistor may comprise a first sidewall and a second sidewall that is opposite to the first sidewall in the first direction. The second transistor may comprise a third sidewall and a fourth sidewall that is opposite to the third sidewall in the first direction between the upper surface of the substrate and the first transistor in a second direction that is perpendicular to the upper surface of the substrate. One of the third sidewall and the fourth sidewall may overlap the first transistor in the second direction.

An integrated circuit device, according to some embodiments, may include a substrate, a first cell structure on an upper surface of the substrate, a second cell structure that is adjacent the first cell structure in a first direction that is parallel with the upper surface of the substrate, a cell boundary between the first cell structure and the second cell structure in the first direction, a first transistor in at least one of the first cell structure and the second cell structure, and a second transistor crossing the cell boundary in the first direction and extending into the first cell structure and the second cell structure. The first transistor may comprise a first sidewall and a second sidewall that is opposite to the first sidewall in the first direction. The second transistor may comprise a third sidewall and a fourth sidewall that is opposite to the third sidewall in the first direction between the upper surface of the substrate and the first transistor in a second direction that is perpendicular to the upper surface of the substrate. One of the third sidewall and the fourth sidewall may overlap the first transistor in the second direction.

### BRIEF DESCRIPTION OF THE DRAWINGS

FIGS. 1A and 1B are a plan view and a cross-sectional view of an integrated circuit device according to some embodiments, respectively.

FIGS. 2A and 2B are a plan view and a cross-sectional view of an integrated circuit device according to some embodiments, respectively.

FIGS. 3A and 3B are a plan view and a cross-sectional view of an integrated circuit device according to some embodiments, respectively.

FIGS. 4A and 4B are a plan view and a cross-sectional view of an integrated circuit device according to some embodiments, respectively.

FIGS. 5A and 5B are a plan view and a cross-sectional view of an integrated circuit device according to some embodiments, respectively.

### DETAILED DESCRIPTION OF EMBODIMENTS

Pursuant to embodiments herein, an integrated circuit device may include an upper transistor and a lower transistor in a Z-shape scheme. For example, the upper transistor and the lower transistor may be staggered with respect to each other in the horizontal direction. In some embodiments, the upper transistor and the lower transistor may be positioned in a zigzag arrangement in the horizontal direction. The upper transistor and the lower transistor may have different sizes (e.g., different cell heights and/or different cell widths). In some embodiments, at least one of the upper transistor and the lower transistor may cross a cell boundary.

Example embodiments will be described in greater detail with reference to the attached figures.

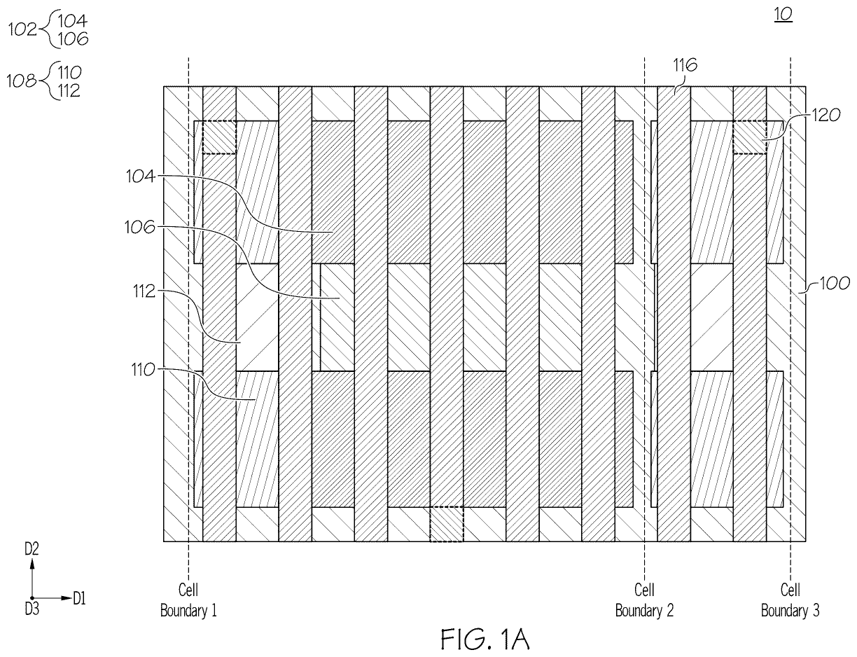

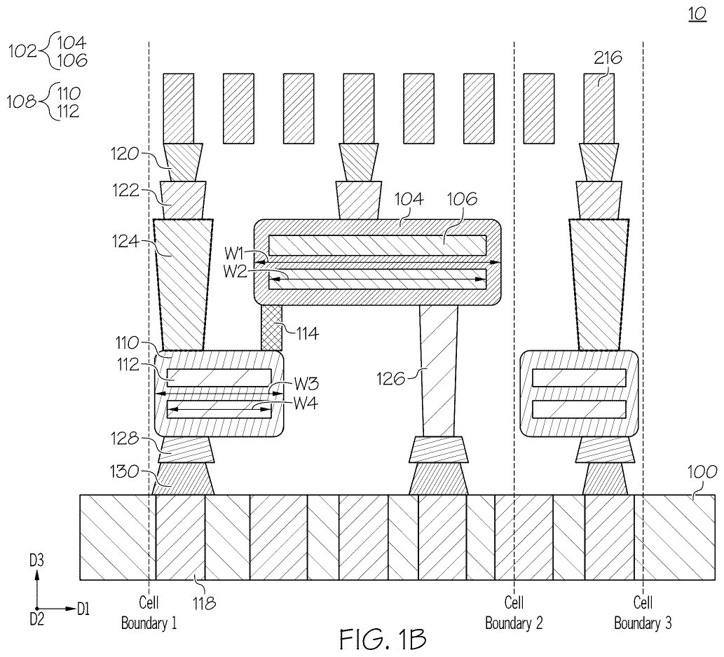

FIGS. 1A and 1B are a plan view and a cross-sectional view of an integrated circuit device 10 according to some embodiments, respectively. FIG. 1A may be a plan view from an upper side of the integrated circuit device 10. For example, FIG. 1A may be a bird's eye view of the top of the integrated circuit device 10. FIG. 1B may be a cross-sectional view (e.g., along the first direction D1) of the integrated circuit device 10 illustrated in FIG. 1A.

Referring to FIGS. 1A and 1B, the integrated circuit device 10 may include a first cell structure on a substrate 100. The integrated circuit device 10 may have a first cell boundary (e.g., cell boundary 1) and a second cell boundary (e.g., cell boundary 2) that is spaced apart from the first cell boundary in a horizontal direction that is parallel with an upper surface of the substrate 100. For example, the first cell boundary and the second cell boundary may be spaced apart from each other in a first direction D1 that is parallel with the upper surface of the substrate 100. The first cell structure may be between the first cell boundary and the second cell boundary in the first direction D1. The second cell boundary may be opposite to the first cell boundary with respect to the first cell structure in the first direction D1. For example, the first cell structure may refer to a region that includes various elements of the integrated circuit device 10 between the first cell boundary and the second cell boundary in the first direction D1.

The integrated circuit device 10 may include a second cell structure on the substrate 100. The second cell structure may be adjacent the first cell structure in the horizontal direction (e.g., in the first direction D1). The integrated circuit device 10 may further have a third cell boundary (e.g., cell boundary 3) that is spaced apart from the second cell boundary (e.g., cell boundary 2) in the horizontal direction (e.g., the first direction D1). For example, the second cell boundary (e.g., cell boundary 2) may be between the first cell boundary (e.g., cell boundary 1) and the third cell boundary (e.g., cell boundary 3) in the first direction D1. The second cell structure may be between the second cell boundary and the third cell boundary in the first direction D1. The third cell boundary may be opposite to the second cell boundary with respect to the second cell structure in the first direction D1. For example, the second cell structure may refer to a region that includes various elements of the integrated circuit device 10 between the second cell boundary and the third cell boundary in the first direction D1.

The substrate 100 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate may be a bulk substrate (e.g., a silicon wafer), a semiconductor on insulator (SOI) substrate or an insulating layer (e.g., a monolithic insulating layer). The low-k material may have a lower dielectric constat than that of silicon oxide (e.g., SiO). The low-k material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric.

Referring to FIGS. 1A and 1B, the first cell structure of the integrated circuit device 10 may include (at least a portion of) a first transistor 102 (e.g., an upper transistor 102) and (at least a portion of) a second transistor 108 (e.g., a lower transistor 108) formed on the substrate 100. The second transistor 108 may be between (the upper surface of) the substrate 100 and the first transistor 102 in a vertical direction that is perpendicular to the upper surface and/or a lower surface of the substrate 100. Herein, the vertical direction may refer to a third direction D3 in the drawings. In some embodiments, the first transistor 102 and the second transistor 108 may be staggered in the first direction D1. For example, the center (or a central portion) of the first transistor 102 and the center (or a central portion) of the second transistor 108 may not overlap (e.g., may be misaligned with) each other in the third direction D3. For example, the center (or the central portion) of the first transistor 102 and the center (or the central portion) of the second transistor 108 may be offset from each other in the first direction D1. In some embodiments, the first transistor 102 may have a first sidewall and a second sidewall that is opposite to the first sidewall in the first direction D1, and the second transistor 108 may have a third sidewall and a fourth sidewall that is opposite to the third sidewall in the first direction D1. The first sidewall and the second sidewall of the first transistor 102 and the third sidewall and the fourth sidewall of the second transistor 108 may not overlap with each other in the third direction D3. For example, a plane of the second sidewall of the first transistor 102 may be between respective planes of the third sidewall and the fourth sidewall of the second transistor 108 in the first direction D1. A plane of the first sidewall of the first transistor 102 may be free of overlap with respective planes of the third sidewall and the fourth sidewall of the second transistor 108 in the third direction D3. For example, a plane of the third sidewall of the second transistor 108 may be between respective planes of the first sidewall and the second sidewall of the first transistor 102 in the first direction D1. For example, a plane of the third sidewall of the second transistor 108 may overlap the first transistor 102 in the third direction D3. A plane of the fourth sidewall of the second transistor 108 may be free of overlap with respective planes of the first sidewall and the second sidewall of the first transistor 102 in the third direction D3. In summary, the first transistor 102 may have a portion that is free of overlap with the second transistor 108 in the third direction D3, and the second transistor 108 may have a portion that is free of overlap with the first transistor 102 in the third direction D3. However, the relative locations of the first transistor 102 and the second transistor 108 are not limited to the embodiments described above. The staggered (zigzag) structure of the first transistor 102 and the second transistor 108 may be referred to as a Z-shape scheme or a Z-shape 3D stacked device (e.g., Z-shape 3D stacked field effect transistor (Z-shape 3DSFET)).

The first transistor 102 and the second transistor 108 may have different conductivity types or the same conductivity type. In some embodiments, the first transistor 102 may include a first source/drain region 104. The first transistor 102 may be a P-type transistor, and the first source/drain region 104 may be a P-type source/drain region. The second transistor 108 may include a second source/drain region 110. The second transistor 108 may be an N-type transistor, and the second source/drain region 110 may be an N-type source/drain region. However, the inventive concepts of the types of the first transistor 102 and the second transistor 108 are not limited to the embodiments described above. For example, the first transistor 102 may be an N-type transistor including an N-type source/drain region (e.g., the first source/drain region 104), and the second transistor 108 may be a P-type transistor including a P-type source/drain region (e.g., the second source/drain region 110). The first transistor 102 and the second transistor 108 may be implemented using various types of transistors (e.g., a planar transistor, a gate-all-around field-effect transistor (GAA FET), a recessed channel array transistor (RCAT), a fin field-effect transistor (FinFET), or multi-bridge-channel field effect transistor (MBCFET™)). Hereinafter, the first transistor 102 and the second transistor 108 are described as MBCFETs™ for the convenience of the description, but the types of the first transistor 102 and the second transistor 108 are not limited thereto.

The first transistor 102 may comprise first channel layers 106 (e.g., upper channel layers) and a first work function layer (e.g., an upper work function layer) (not illustrated) on the first channel layers 106. The first transistor 102 may further comprise first gate insulators (e.g., upper gate insulators) (not illustrated) on the first channel layers 106, and a first gate electrode (e.g., an upper gate electrode) (not illustrated) on the first work function layer. For example, the first gate insulators may be between the first channel layers 106 and the first work function layer. The first gate insulators, the first work function layer, and the first gate electrode may be collectively referred to as a first gate structure (e.g., an upper gate structure).

The first channel layers 106 may be spaced apart from each other in the vertical direction (e.g., in the third direction D3). In some embodiments, the first channel layers 106 may be spaced apart from each other at equal or substantially equal distance in the vertical direction. In some embodiments, each of the first channel layers 106 may have an equal or a substantially equal width in the first direction D1 and a second direction D2 that is parallel with an upper surface of the substrate and intersects the first direction D1. The second direction D2 may be perpendicular to the first direction D1. Herein, “substantially” may mean no greater than a 10% deviation. For example, when element X has a width of 10 nm and a width of element Y is substantially equal to that of element X, the width of element Y may not be less than 9 nm or greater than 11 nm.

The first gate insulators may extend around (e.g., at least partially surround) the first channel layers 106, respectively. The first work function layer may extend around (e.g., at least partially surround) the first gate insulators (and the first channel layers 106). The first gate electrode may extend around (e.g., at least partially surround) the first work function layer.

In some embodiments, the first channel layers 106 may include semiconductor material(s), for example, Si, Ge, SiGe, GaP, GaAs, SiC, SiGeC and/or InP. In some embodiments, the first gate insulators may include insulator(s), for example, silicon oxide, silicon oxynitride, silicon nitride, silicon carbonitride and/or a low-k material that has a lower dielectric constant than that of silicon oxide. In some embodiments, the first work function layer may include, for example, a TiN layer, a TaN layer, a TiAl layer, a TiC layer, a TiAlC layer, a TiAlN layer and/or a WN layer. In some embodiments, the first gate electrode may include, for example, tungsten (W), aluminum (Al) and/or copper (Cu). However, the materials of the first channel layers 106, the first gate insulators, the first work function layer, and the first gate electrode are not limited to the embodiments described above. In some embodiments, the first gate insulators and the first gate electrode may be omitted.

The second transistor 108 may comprise second channel layers 112 (e.g., lower channel layers 112) and a second work function layer (e.g., a lower work function layer) (not illustrated) on the second channel layers 112. The second transistor 108 may further comprise second gate insulators (e.g., lower gate insulators) (not illustrated) on the second channel layers 112, and a second gate electrode (e.g., a lower gate electrode) (not illustrated) on the second work function layer. For example, the second gate insulators may be between the second channel layers 112 and the second work function layer. The second gate insulators, the second work function layer, and the second gate electrode may be collectively referred to as a second gate structure (e.g., a lower gate structure).

The second channel layers 112 may be spaced apart from each other in the vertical direction (e.g., in the third direction D3). In some embodiments, the second channel layers 112 may be spaced apart from each other at equal or substantially equal distance in the vertical direction. In some embodiments, each of the second channel layers 112 may have an equal or a substantially equal width in the first direction D1 and/or the second direction D2. In some embodiments the width of the first channel layers 106 in the first direction D1 may be (substantially) the same as the width of the second channel layers 112 in the first direction D1. In some embodiments, the width of the first channel layers 106 in the second direction D2 may be (substantially) the same as the width of the second channel layers 112 in the second direction D2. However, the relative widths of the first channel layers 106 and the second channel layers 112 in the first direction D1 and the second direction D2 are not limited thereto.

The second gate insulators may extend around (e.g., at least partially surround) the second channel layers 112, respectively. The second work function layer may extend around (e.g., at least partially surround) the second gate insulators. The second gate electrode may extend around (e.g., at least partially surround) the second work function layer.

In some embodiments, the second channel layers 112 may include semiconductor material(s), for example, Si, Ge, SiGe, GaP, GaAs, SiC, SiGeC and/or InP. In some embodiments, the second gate insulators may include insulator(s), for example, silicon oxide, silicon oxynitride, silicon nitride, silicon carbonitride and/or a low-k material that has a lower dielectric constant than that of silicon oxide. In some embodiments, the second work function layer may include, for example, a TiN layer, a TaN layer, a TiAl layer, a TiC layer, a TiAlC layer, a TiAlN layer and/or a WN layer. In some embodiments, the second gate electrode may include, for example, tungsten (W), aluminum (Al) and/or copper (Cu). However, the materials of the second channel layers 112, the second gate insulators, the second work function layer, and the second gate electrode are not limited to the embodiments described above. In some embodiments, the second gate insulators and the second gate electrode may be omitted.

In some embodiments, each of the first channel layers 106 and the second channel layers 112 may be a nanosheet (that may have a thickness in a range of from 1 nm to 100 nm in the vertical direction) or may be a nanowire (that may have a circular cross-section with a diameter in a range of from 1 nm to 100 nm). The number of the first channel layers 106 and the number of the second channel layers 112 may vary.

The integrated circuit device 10 may include an insulator 114 (also referred to as an inter-gate insulator 114 or a middle dielectric isolation 114) between the first transistor 102 and the second transistor 108 in the third direction D3. The insulator 114 may include insulator(s), for example, silicon nitride (e.g., SiN). However, the material of the insulator 114 is not limited thereto.

The integrated circuit device 10 may include front-side conductive tracks 116 on (the upper surface of) the first transistor 102. The front-side conductive tracks 116 may be spaced apart from each other in the first direction D1. Although not illustrated, an interlayer insulating layer may extend around (e.g., at least partially surround) the front-side conductive tracks 116. The front-side conductive tracks 116 may be spaced apart from each other by (substantially) the same distance in the first direction D1. In some embodiments, the front-side conductive tracks 116 may be spaced apart from each other by different distances in the first direction D1. In some embodiments, each of the front-side conductive tracks 116 may have the same or substantially the same width in the first direction D1. In some embodiments, one of the front-side conductive tracks 116 may have a width in the first direction D1 different from a width of another one of the front-side conductive tracks 116 in the first direction D1. In some embodiments, the distance between adjacent ones of the front-side conductive tracks 116 in the first direction D1 may be equal or substantially equal to the width of one of the front-side conductive tracks 116 in the first direction D1.

The front-side conductive tracks 116 may be within the cell structure (e.g., the first cell structure and/or the second cell structure). For example, the front-side conductive tracks 116 may be between the first cell boundary and the second cell boundary in the first direction D1 and/or between the second cell boundary and the third cell boundary in the first direction D1. However, the embodiments of the front-side conductive tracks 116 are not limited thereto. For example, the front-side conductive tracks 116 may overlap the first cell boundary, the second cell boundary, and/or the third cell boundary in the third direction D3. Although six (6) front-side conductive tracks 116 between the first cell boundary and the second cell boundary (in the first cell structure), and two (2) front-side conductive tracks 116 between the second cell boundary and the third cell boundary (in the second cell structure) are illustrated in FIGS. 1A and 1B, the number of the front-side conductive tracks 116 is not limited thereto. For example, the number of the front-side conductive tracks 116 in the first cell structure and the number of the front-side conductive tracks 116 in the second cell structure may be equal. In some embodiments, the front-side conductive tracks 116 may include a conductive material, such as a metal. For example, the front-side conductive tracks 116 may include copper, aluminum, and/or tungsten, but not limited thereto. In some embodiments, the front-side conductive tracks 116 may be configured to function as signal transfer paths (tracks) and/or a front-side power delivery network (FSPDN) for the integrated circuit device 10. For example, the front-side conductive tracks 116 may be configured to transfer a signal to or from at least one of the first transistor 102 and the second transistor 108 through a conductive contact (e.g., the front-side upper conductive contact 122). For example, the front-side conductive tracks 116 may be configured to supply power to at least one of the first transistor 102 and the second transistor 108 through a conductive contact (e.g., the front-side upper conductive contact 122).

The integrated circuit device 10 may include back-side conductive tracks 118 on (below)/in the substrate 100. In some embodiments, the back-side conductive tracks 118 may be in the substrate 100. In some embodiments, the back-side conductive tracks 118 may be on a lower surface of the substrate 100. For example, the integrated circuit device 10 may include back-side conductive tracks 118 on (below) the second transistor 108. Although not illustrated, an interlayer insulating layer may extend around (e.g., at least partially surround) the back-side conductive tracks 118. The back-side conductive tracks 118 may be spaced apart from each other in the first direction D1. The back-side conductive tracks 118 may be spaced apart from each other by (substantially) the same distance in the first direction D1. In some embodiments, the back-side conductive tracks 118 may be spaced apart from each other by different distances in the first direction D1. In some embodiments, each of the back-side conductive tracks 118 may have the same or substantially the same width in the first direction D1. In some embodiments, one of the back-side conductive tracks 118 may have a width in the first direction D1 different from a width of another one of the back-side conductive tracks 118 in the first direction D1. In some embodiments, the distance between adjacent ones of the back-side conductive tracks 118 in the first direction D1 may be equal or substantially equal to the width of the back-side conductive track 118 in the first direction D1.

The back-side conductive tracks 118 may be within the cell structure (e.g., the first cell structure and/or the second cell structure). For example, the back-side conductive tracks 118 may be between the first cell boundary and the second cell boundary in the first direction D1 and/or between the second cell boundary and the third cell boundary in the first direction D1. However, the embodiments of the back-side conductive tracks 118 are not limited thereto. For example, the back-side conductive tracks 118 may overlap the first cell boundary, the second cell boundary, and/or the third cell boundary in the third direction D3. Although four and half (4.5) back-side conductive tracks 118 between the first cell boundary and the second cell boundary (in the first cell structure), and one and half (1.5) back-side conductive tracks 118 between the second cell boundary and the third cell boundary (in the second cell structure) are illustrated in FIGS. 1A and 1B, the number of the back-side conductive tracks 118 is not limited thereto. For example, the number of the back-side conductive tracks 118 in the first cell structure and the number of the back-side conductive tracks 118 in the second cell structure may be equal. In some embodiments, in a cell structure, the number of the back-side conductive tracks 118 may be the same as the number of the front-side conductive tracks 116. In some embodiments, the back-side conductive tracks 118 may include a conductive material, such as a metal. For example, the back-side conductive tracks 118 may include copper, aluminum, and/or tungsten, but not limited thereto. In some embodiments, the back-side conductive tracks 118 may be configured to perform as signal transfer paths (tracks) and/or a back-side power delivery network (BSPDN) for the integrated circuit device 10. For example, the back-side conductive tracks 118 may be configured to transfer a signal to or from at least one of the first transistor 102 and the second transistor 108 through a conductive contact (e.g., the back-side lower conductive contact 128). For example, the back-side conductive tracks 118 may be configured to supply power to at least one of the first transistor 102 and the second transistor 108 through a conductive contact (e.g., the back-side lower conductive contact 128).

The integrated circuit device 10 may further include a middle-of-line (MOL) structure. The MOL structure may include interlayer insulating layer(s) in which conductive wire(s) (e.g., metal wire(s)), conductive via(s) (e.g., metal via(s)), and/or conductive contact(s) (e.g., metal contact(s)) are provided. Various elements of the first transistor 102 and the second transistor 108 may be (electrically) connected to the MOL structure. In some embodiments, the front-side conductive tracks 116 and/or the back-side conductive tracks 118 may be electrically connected to the first transistor 102 and/or the second transistor 108 through the MOL structure.

Referring to FIGS. 1A and 1B, for example, the MOL structure may include front-side conductive vias 120, a front-side upper conductive contact 122, a front-side lower conductive contact 124, a back-side upper conductive contact 126, a back-side lower conductive contact 128, and back-side conductive vias 130. However, the MOL structure is not limited to the embodiments described above. For example, the MOL structure may include an additional element that is not described above, or some of the elements of the MOL structure described above may be omitted or integrated with each other.

In some embodiments, the front-side conductive vias 120 may be between the front-side conductive tracks 116 and a transistor (e.g., the first transistor 102 and/or the second transistor 108) in the third direction D3. The front-side upper conductive contact 122 may be between (corresponding) one of the front-side conductive vias 120 and a transistor (e.g., the first transistor 102 and/or the second transistor 108) in the third direction D3. The front-side lower conductive contact 124 may be between the front-side upper conductive contact 122 and a transistor (e.g., the first transistor 102 and/or the second transistor 108) in the third direction D3.

In some embodiments, the back-side upper conductive contact 126 may be between the back-side conductive tracks 118 and a transistor (e.g., the first transistor 102 or the second transistor 108) in the third direction D3. The back-side lower conductive contact 128 may be between the back-side upper conductive contact 126 and the back-side conductive tracks 118 in the third direction D3. The back-side conductive vias 130 may be between the back-side lower conductive contact 128 and the back-side conductive tracks 118 in the third direction D3.

The elements of the MOL structure in the Z-shape scheme may not overlap the target transistor (e.g., the first transistor 102 or the second transistor 108) in a horizontal direction (e.g., in the first direction D1 or the second direction D2). The target transistor herein may refer to a transistor that is intended to be (electrically) connected to the elements of the MOL structure. Referring to FIG. 1B, for example, the front-side conductive via 120 and the front-side upper conductive contact 122 (electrically) connected to the first transistor 102 may not overlap the first transistor 102 in the first direction D1 or the second direction D2. Referring to FIG. 1B, for example, the front-side conductive via 120, the front-side upper conductive contact 122, and the front-side lower conductive contact 124 (electrically) connected to the second transistor 108 may not overlap the second transistor 108 in the first direction D1 or the second direction D2. Referring to FIG. 1B, for example, the back-side upper conductive contact 126, the back-side lower conductive contact 128, and the back-side conductive via 130 (electrically) connected to the first transistor 102 may not overlap the first transistor 102 in the first direction D1 or the second direction D2. Referring to FIG. 1B, for example, the back-side lower conductive contact 128 and the back-side conductive via 130 (electrically) connected to the second transistor 108 may not overlap the second transistor 108 in the first direction D1 or the second direction D2. The (electrical) connection between elements of the MOL structure and the target transistor without a detour in a space between the target transistor (e.g., the sidewall of the target transistor facing the adjacent cell boundary) and the adjacent cell boundary may be referred to as a direct contact scheme.

In some embodiments, at least a portion of the first transistor 102 in the first cell structure may have a width in the first direction D1 that is different from a width in the first direction D1 of at least a portion of the second transistor 108 in the first cell structure. For example, the at least a portion of the first transistor 102 in the first cell structure may have a greater width in the first direction D1 than a width in the first direction D1 of the at least a portion of the second transistor 108 in the first cell structure. The at least a portion of the first transistor 102 in the first cell structure may have a less width in the first direction D1 than a width in the first direction D1 of the at least a portion of the second transistor 108 in the first cell structure.

In some embodiments, the first transistor 102 may have a first cell width W1 in a horizontal direction. For example, the first transistor 102 may have the first cell width W1 in the first direction D1. The first cell width W1 may be referred to as a first cell height W1. In some embodiments, the first channel layer 106 may have a first channel width W2 in a horizontal direction. For example, the first channel layer 106 may have the first channel width W2 in the first direction D1. The first cell width W1 may be equal to or greater than the first channel width W2.

In some embodiments, the second transistor 108 may have a second cell width W3 in a horizontal direction. For example, the second transistor 108 may have the second cell width W3 in the first direction D1. The second cell width W3 may be referred to as a second cell height W3. In some embodiments, the second channel layer 112 may have a second channel width W4 in a horizontal direction. For example, the second channel layer 112 may have the second channel width W4 in the first direction D1. The second cell width W3 may be equal to or greater than the second channel width W4.

The second cell structure that is adjacent the first cell structure in a horizontal direction (e.g., the first direction D1) may comprise (substantially) the same elements of the first cell structure described above. In some embodiments, the structure and shape of the second cell structure may be (substantially) the same as those of the first cell structure. However, the embodiments of the shape of the second cell structure and the elements therein are not limited thereto. For example, some of the elements of the first cell structure described above may be modified or omitted in the second cell structure. In some embodiments, at least some elements of the first cell structure and the corresponding elements of the second cell structure may be (substantially) symmetrical to each other with respect to the second cell boundary in the first direction D1. For example, at least some elements of the first cell structure and the corresponding elements of the second cell structure may comprise a mirror-image to each other in the first direction D1.

Referring to FIGS. 1A and 1B, the first cell structure may include the first transistor 102 and the second transistor 108. The second cell structure may include a transistor corresponding to the second transistor 108 of the first cell structure. The corresponding transistor of the second cell structure and the second transistor 108 of the first cell structure may be symmetrical (e.g., may comprise a mirror-image) to each other in the first direction D1. However, the elements and the configurations thereof in the second cell structure are not limited to the embodiments described above.

Referring to FIGS. 1A and 1B, the first cell width W1 may be greater than the second cell width W3. The first channel width W2 may be greater than the second channel width W4. In some embodiments, the first cell width W1 may be time and a half (1.5 times) of the second cell width W3, but the difference between the first cell width W1 and the second cell width W3 is not limited thereto. In some embodiments, the first transistor 102 may be positioned adjacent the second cell boundary with no MOL structure therebetween in the first direction D1.

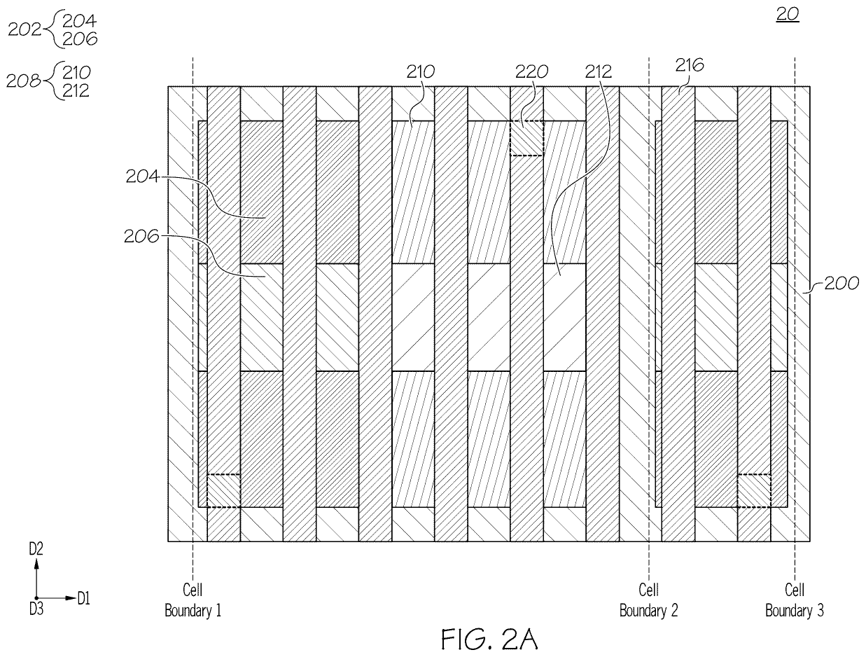

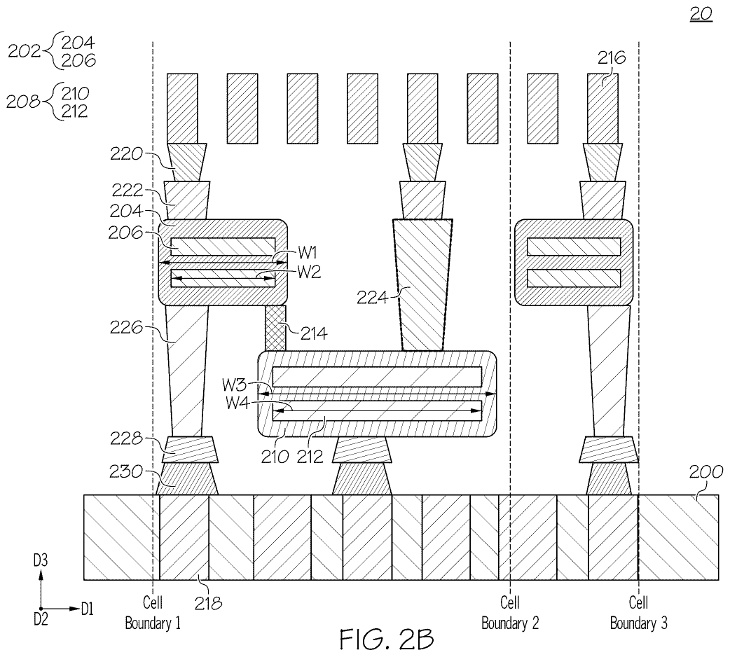

FIGS. 2A and 2B are a plan view and a cross-sectional view of an integrated circuit device 20 according to some embodiments, respectively. FIG. 2A may be a plan view from an upper side of the integrated circuit device 20. For example, FIG. 2A may be a bird's eye view of the top of the integrated circuit device 20. FIG. 2B may be a cross-sectional view (e.g., along the first direction D1) of the integrated circuit device 20 illustrated in FIG. 2A.

Since the integrated circuit device 20 may be (at least partially) formed and configured similarly as the integrated circuit device 10 in FIGS. 1A and 1B, detailed descriptions of the common configuration with the integrated circuit device 10 may be omitted, and differences from the integrated circuit device 10 will be described in detail. The substrate 200, the first transistor 202, the first source/drain region 204, the first channel layers 206, the second transistor 208, the second source/drain region 210, the second channel layers 212, the insulator 214, the front-side conductive tracks 216, the back-side conductive tracks 218, the front-side conductive vias 220, the front-side upper conductive contact 222, the front-side lower conductive contact 224, the back-side upper conductive contact 226, the back-side lower conductive contact 228, and the back-side conductive vias 230 in FIGS. 2A and 2B may correspond to the substrate 100, the first transistor 102, the first source/drain region 104, the first channel layers 106, the second transistor 108, the second source/drain region 110, the second channel layers 112, the insulator 114, the front-side conductive tracks 116, the back-side conductive tracks 118, the front-side conductive vias 120, the front-side upper conductive contact 122, the front-side lower conductive contact 124, the back-side upper conductive contact 126, the back-side lower conductive contact 128, and the back-side conductive vias 130 in FIGS. 1A and 1B, respectively.

Referring to FIGS. 2A and 2B, the first cell structure may include the first transistor 202 and the second transistor 208. The second cell structure may include a transistor corresponding to the first transistor 202 of the first cell structure. The corresponding transistor of the second cell structure and the first transistor 202 of the first cell structure may be symmetrical (e.g., may comprise a mirror-image) to each other in the first direction D1. However, the elements and the configurations thereof in the second cell structure are not limited to the embodiments described above.

Referring to FIGS. 2A and 2B, the second cell width W3 may be greater than the first cell width W1. The second channel width W4 may be greater than the first channel width W2. In some embodiments, the second cell width W3 may be one and half times (1.5 times) of the first cell width W1, but the difference between the first cell width W1 and the second cell width W3 is not limited thereto. In some embodiments, the second transistor 208 may be positioned adjacent the second cell boundary with no MOL structure therebetween in the first direction D1.

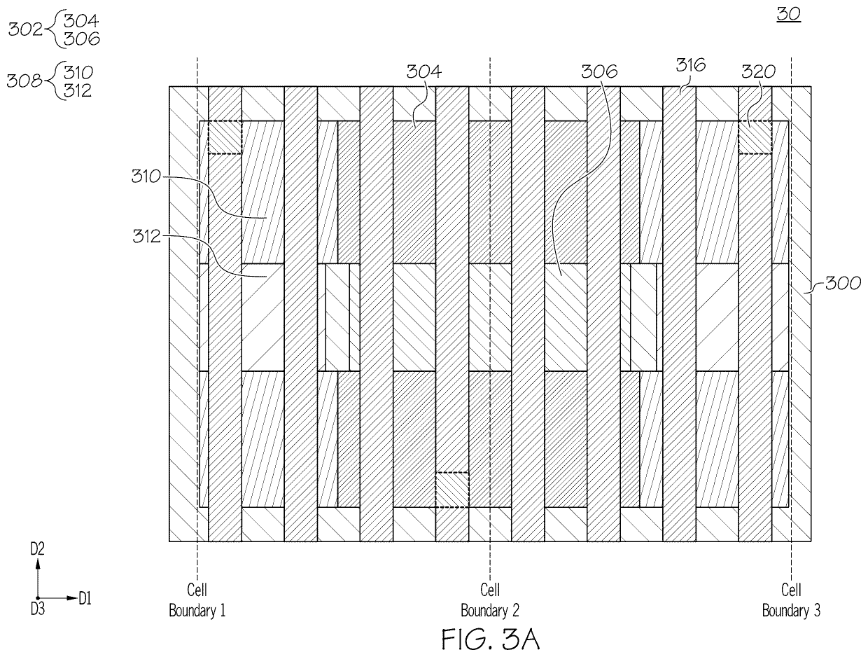

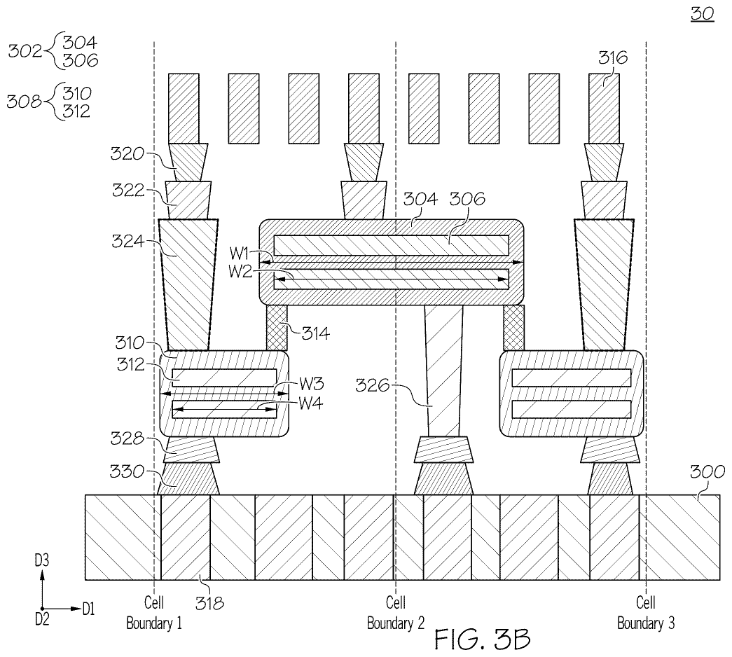

FIGS. 3A and 3B are a plan view and a cross-sectional view of an integrated circuit device 30 according to some embodiments, respectively. FIG. 3A may be a plan view from an upper side of the integrated circuit device 30. For example, FIG. 3A may be a bird's eye view of the top of the integrated circuit device 30. FIG. 3B may be a cross-sectional view (e.g., along the first direction D1) of the integrated circuit device 30 illustrated in FIG. 3A.

Since the integrated circuit device 30 may be (at least partially) formed and configured similarly as the integrated circuit device 10 in FIGS. 1A and 1B, detailed descriptions of the common configuration with the integrated circuit device 10 may be omitted, and differences from the integrated circuit device 10 will be described in detail. The substrate 300, the first transistor 302, the first source/drain region 304, the first channel layers 306, the second transistor 308, the second source/drain region 310, the second channel layers 312, the insulator 314, the front-side conductive tracks 316, the back-side conductive tracks 318, the front-side conductive vias 320, the front-side upper conductive contact 322, the front-side lower conductive contact 324, the back-side upper conductive contact 326, the back-side lower conductive contact 328, and the back-side conductive vias 330 in FIGS. 3A and 3B may correspond to the substrate 100, the first transistor 102, the first source/drain region 104, the first channel layers 106, the second transistor 108, the second source/drain region 110, the second channel layers 112, the insulator 114, the front-side conductive tracks 116, the back-side conductive tracks 118, the front-side conductive vias 120, the front-side upper conductive contact 122, the front-side lower conductive contact 124, the back-side upper conductive contact 126, the back-side lower conductive contact 128, and the back-side conductive vias 130 in FIGS. 1A and 1B, respectively.

Referring to FIGS. 3A and 3B, the first transistor 302 may cross the second cell boundary between the first cell structure and the second cell structure in the first direction D1. For example, the first transistor 302 may extend into the first cell structure and the second cell structure. In some embodiments, the first channel layer 306 may cross the second cell boundary between the first cell structure and the second cell structure in the first direction D1. For example, the first channel layer 306 may extend into the first cell structure and the second cell structure. The second cell structure may include a transistor corresponding to the second transistor 308 of the first cell structure. The corresponding transistor of the second cell structure and the second transistor 308 of the first cell structure may be symmetrical (e.g., may comprise a mirror-image) to each other in the first direction D1. However, the elements and the configurations thereof in the second cell structure are not limited to the embodiments described above.

Referring to FIGS. 3A and 3B, the first cell width W1 may be greater than the second cell width W3. The first channel width W2 may be greater than the second channel width W4. In some embodiments, the first cell width W1 may be twice (double) the second cell width W3, but the difference between the first cell width W1 and the second cell width W3 is not limited thereto. For example, the first cell width W1 may be four (4) times or eight (8) times of the second cell width W3 as necessary. In some embodiments, a portion of the first transistor 302 in the first cell structure and a portion of the first transistor 302 in the second cell structure may be integrated to each other without intervening external elements (e.g., the MOL structure) therebetween in the first direction D1. In some embodiments, a portion of the first channel layer 306 in the first cell structure and a portion of the first channel layer 306 in the second cell structure may be integrated to each other without intervening external elements (e.g., the MOL structure) therebetween in the first direction D1.

Referring to FIGS. 3A and 3B, a width in the first direction D1 of a portion of the first transistor 302 in the first cell structure (or in the second cell structure) may be greater than the second cell width W3. In some embodiments, a width in the first direction D1 of a portion of the first channel layer 306 in the first cell structure (or in the second cell structure) may be greater than the second channel width W4.

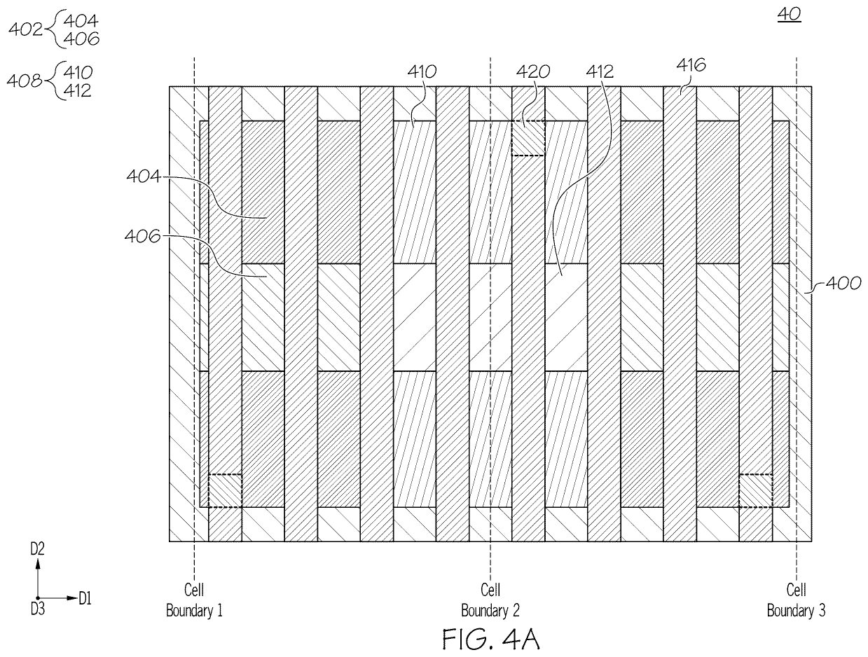

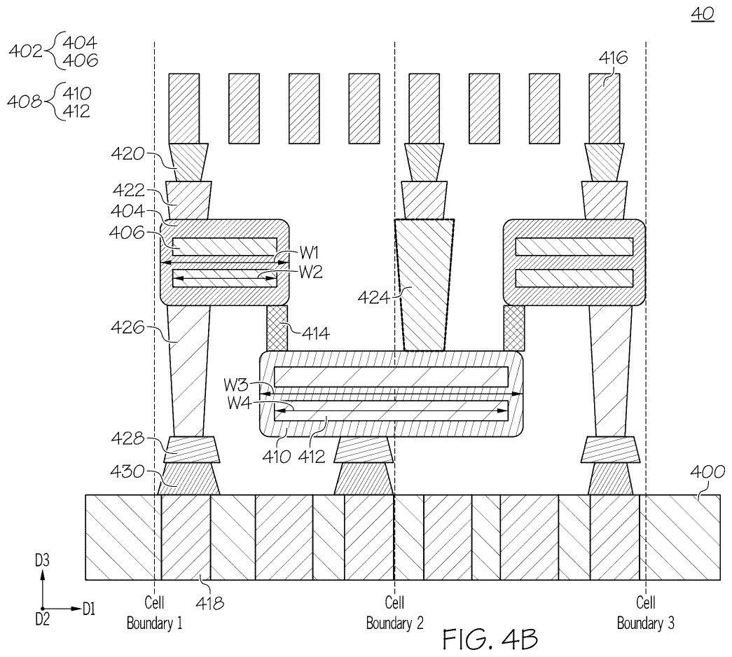

FIGS. 4A and 4B are a plan view and a cross-sectional view of an integrated circuit device 40 according to some embodiments, respectively. FIG. 4A may be a plan view from an upper side of the integrated circuit device 40. For example, FIG. 4A may be a bird's eye view of the top of the integrated circuit device 40. FIG. 4B may be a cross-sectional view (e.g., along the first direction D1) of the integrated circuit device 40 illustrated in FIG. 4A.

Since the integrated circuit device 40 may be (at least partially) formed and configured similarly as the integrated circuit device 30 in FIGS. 3A and 3B, detailed descriptions of the common configuration with the integrated circuit device 30 may be omitted, and differences from the integrated circuit device 30 will be described in detail. The substrate 400, the first transistor 402, the first source/drain region 404, the first channel layers 406, the second transistor 408, the second source/drain region 410, the second channel layers 412, the insulator 414, the front-side conductive tracks 416, the back-side conductive tracks 418, the front-side conductive vias 420, the front-side upper conductive contact 422, the front-side lower conductive contact 424, the back-side upper conductive contact 426, the back-side lower conductive contact 428, and the back-side conductive vias 430 in FIGS. 4A and 4B may correspond to the substrate 300, the first transistor 302, the first source/drain region 304, the first channel layers 306, the second transistor 308, the second source/drain region 310, the second channel layers 312, the insulator 314, the front-side conductive tracks 316, the back-side conductive tracks 318, the front-side conductive vias 320, the front-side upper conductive contact 322, the front-side lower conductive contact 324, the back-side upper conductive contact 326, the back-side lower conductive contact 328, and the back-side conductive vias 330 in FIGS. 3A and 3B, respectively.

Referring to FIGS. 4A and 4B, the second transistor 408 may cross the second cell boundary between the first cell structure and the second cell structure in the first direction D1. For example, the second transistor 408 may extend into the first cell structure and the second cell structure. In some embodiments, the second channel layer 412 may cross the second cell boundary between the first cell structure and the second cell structure in the first direction D1. For example, the second channel layer 412 may extend into the first cell structure and the second cell structure. The second cell structure may include a transistor corresponding to the first transistor 402 of the first cell structure. The corresponding transistor of the second cell structure and the first transistor 402 of the first cell structure may be symmetrical (e.g., may comprise a mirror-image) to each other in the first direction D1. However, the elements and the configurations thereof in the second cell structure are not limited to the embodiments described above.

Referring to FIGS. 4A and 4B, the second cell width W3 may be greater than the first cell width W1. The second channel width W4 may be greater than the first channel width W2. In some embodiments, the second cell width W3 may be twice (double) the first cell width W1, but the difference between the first cell width W1 and the second cell width W3 is not limited thereto. For example, the second cell width W3 may be four (4) times or eight (8) times of the first cell width W1 as necessary. In some embodiments, a portion of the second transistor 408 in the first cell structure and a portion of the second transistor 408 in the second cell structure may be integrated to each other without intervening external elements (e.g., the MOL structure) therebetween in the first direction D1. In some embodiments, a portion of the second channel layer 412 in the first cell structure and a portion of the second channel layer 412 in the second cell structure may be integrated to each other without intervening external elements (e.g., the MOL structure) therebetween in the first direction D1.

Referring to FIGS. 4A and 4B, a width in the first direction D1 of a portion of the second transistor 408 in the first cell structure (or in the second cell structure) may be greater than the first cell width W1. In some embodiments, a width in the first direction D1 of a portion of the second channel layer 412 in the first cell structure (or in the second cell structure) may be greater than the first channel width W2.

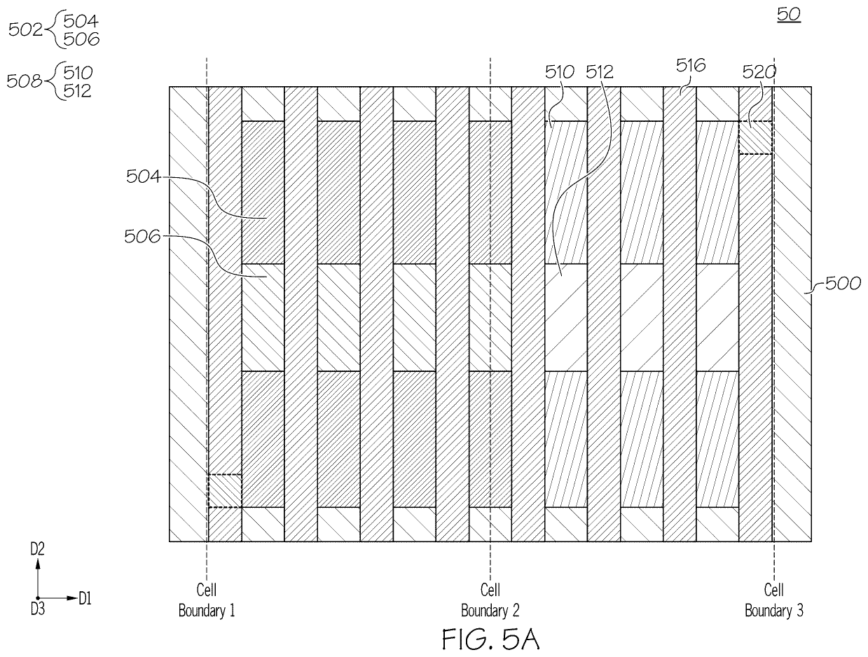

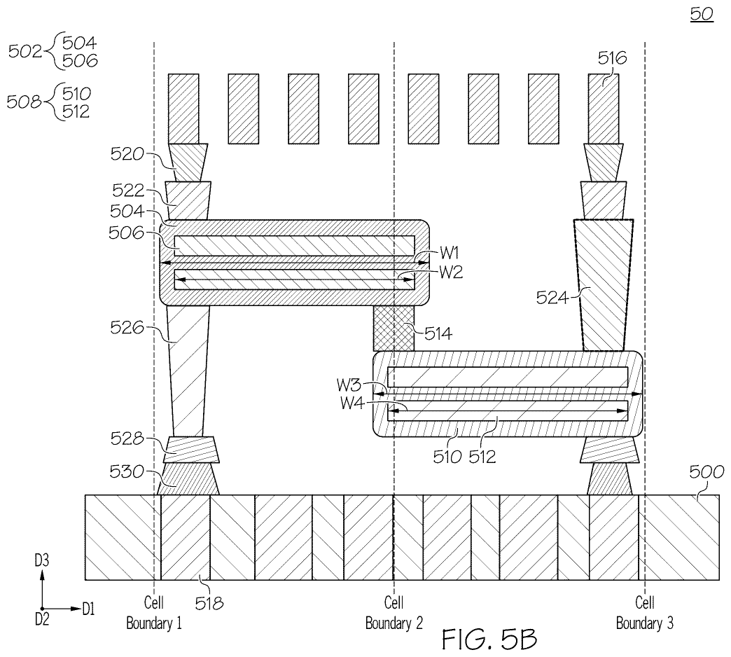

FIGS. 5A and 5B are a plan view and a cross-sectional view of an integrated circuit device 50 according to some embodiments, respectively. FIG. 5A may be a plan view from an upper side of the integrated circuit device 50. For example, FIG. 5A may be a bird's eye view of the top of the integrated circuit device 50. FIG. 5B may be a cross-sectional view (e.g., along the first direction D1) of the integrated circuit device 50 illustrated in FIG. 5A.

Since the integrated circuit device 50 may be (at least partially) formed and configured similarly as the integrated circuit device 30 in FIGS. 3A and 3B, detailed descriptions of the common configuration with the integrated circuit device 30 may be omitted, and differences from the integrated circuit device 30 will be described in detail. The substrate 500, the first transistor 502, the first source/drain region 504, the first channel layers 506, the second transistor 508, the second source/drain region 510, the second channel layers 512, the insulator 514, the front-side conductive tracks 516, the back-side conductive tracks 518, the front-side conductive vias 520, the front-side upper conductive contact 522, the front-side lower conductive contact 524, the back-side upper conductive contact 526, the back-side lower conductive contact 528, and the back-side conductive vias 530 in FIGS. 5A and 5B may correspond to the substrate 300, the first transistor 302, the first source/drain region 304, the first channel layers 306, the second transistor 308, the second source/drain region 310, the second channel layers 312, the insulator 314, the front-side conductive tracks 316, the back-side conductive tracks 318, the front-side conductive vias 320, the front-side upper conductive contact 322, the front-side lower conductive contact 324, the back-side upper conductive contact 326, the back-side lower conductive contact 328, and the back-side conductive vias 330 in FIGS. 3A and 3B, respectively.

Referring to FIGS. 5A and 5B, the first transistor 502 and the second transistor 508 may cross the second cell boundary between the first cell structure and the second cell structure in the first direction D1. For example, each of the first transistor 502 and the second transistor 508 may extend into the first cell structure and the second cell structure. In some embodiments, the first channel layer 506 and the second channel layer 512 may cross the second cell boundary between the first cell structure and the second cell structure in the first direction D1. For example, each of the first channel layer 506 and the second channel layer 512 may extend into the first cell structure and the second cell structure.

Referring to FIGS. 5A and 5B, the second cell width W3 may be (substantially) equal to the first cell width W1. The second channel width W4 may be (substantially) equal to the first channel width W2. However, the relative values of the first cell width W1, the second cell width W3, the first channel width W2, and the second channel width W4 are not limited thereto. In some embodiments, a portion of the first transistor 502 in the first cell structure and a portion of the first transistor 502 in the second cell structure may be integrated to each other without intervening external elements (e.g., the MOL structure) therebetween in the first direction D1. In some embodiments, a portion of the first channel layer 506 in the first cell structure and a portion of the first channel layer 506 in the second cell structure may be integrated to each other without intervening external elements (e.g., the MOL structure) therebetween in the first direction D1. In some embodiments, a portion of the second transistor 508 in the first cell structure and a portion of the second transistor 508 in the second cell structure may be integrated to each other without intervening external elements (e.g., the MOL structure) therebetween in the first direction D1. In some embodiments, a portion of the second channel layer 512 in the first cell structure and a portion of the second channel layer 512 in the second cell structure may be integrated to each other without intervening external elements (e.g., the MOL structure) therebetween in the first direction D1. The first transistor 502 and the second transistor 508 may overlap each other in the third direction D3 at the second cell boundary.

Example embodiments described herein may improve (e.g., increase) the flexibility of the cell height of the transistor of the integrated circuit device by utilizing the staggered transistors (Z-shape scheme), a direct contact scheme, and an area adjacent a cell boundary, which does not include the MOL structure therein. For example, when the upper transistor and the lower transistor are different types of transistors (e.g., P-type transistor and N-type transistor), the sizes of the transistors (e.g., cell heights and/or channel widths) may be adjusted (e.g., maximized) for the controlling and synchronizing of the input/output (I/O) timings of the transistors in different types or other special purposes (e.g., switch cells) by utilizing the Z-shape scheme, the direct contact scheme, and the areas adjacent the cell boundary without the MOL structure therein. For example, the areas adjacent the cell boundary without the MOL structure therein may provide extra space in which the transistors (e.g., the upper transistor and the lower transistor) extend further and have greater sizes. However, it will be understood that the embodiments, goals, and benefits of the present disclosure are not limited to the descriptions above.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present inventive concepts to those skilled in the art. In the drawings, the sizes and relative sizes of layers and regions may be exaggerated for clarity. Like reference numbers may refer to like elements throughout unless clearly stated otherwise.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

As used herein, “an element A overlapping an element B in a direction X” (or similar language) means that there is at least one line that extends in the direction X and intersects both the elements A and B.

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Many different embodiments have been disclosed herein, in connection with the above description and the drawings. It will be understood that it would be unduly repetitious and obfuscating to literally describe and illustrate every combination and sub-combination of these embodiments. Accordingly, the present specification, including the drawings, shall be construed to constitute a complete written description of all combinations and sub-combinations of the embodiments described herein, and of the manner and process of making and using them, and shall support claims to any such combination or sub-combination.

The above-disclosed subject matter is to be considered illustrative, and not restrictive, and the appended claims are intended to cover all such modifications, enhancements, and other embodiments, which fall within the scope of the present inventive concepts. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate; and
a cell structure on an upper surface of the substrate,
wherein the cell structure comprises:
at least a portion of a first transistor that comprises a first sidewall and a second sidewall that is opposite to the first sidewall in a first direction that is parallel with the upper surface of the substrate; and
at least a portion of a second transistor that comprises a third sidewall and a fourth sidewall that is opposite to the third sidewall in the first direction between the upper surface of the substrate and the first transistor in a second direction that is perpendicular to the upper surface of the substrate,
wherein one of the third sidewall and the fourth sidewall overlaps the first transistor in the second direction,
wherein the at least the portion of the first transistor has a first cell width in the first direction,
wherein the at least the portion of the second transistor has a second cell width in the first direction, and
wherein the first cell width is different from the second cell width.

2. The integrated circuit device of claim 1, wherein the first cell width is greater than the second cell width.

3. The integrated circuit device of claim 2, wherein the first transistor further comprises a first channel layer that has a first channel width in the first direction within the cell structure,
wherein the second transistor further comprises a second channel layer that has a second channel width in the first direction within the cell structure, and
wherein the first channel width is greater than the second channel width.

4. The integrated circuit device of claim 1, wherein the second cell width is greater than the first cell width.

5. The integrated circuit device of claim 4, wherein the first transistor further comprises a first channel layer that has a first channel width in the first direction within the cell structure,
wherein the second transistor further comprises a second channel layer that has a second channel width in the first direction within the cell structure, and
wherein the second channel width is greater than the first channel width.

6. The integrated circuit device of claim 1, wherein another one of the third sidewall and the fourth sidewall is free of overlap with the first transistor in the second direction.

7. An integrated circuit device comprising:
a substrate;
a first cell structure on an upper surface of the substrate;
a second cell structure that is adjacent the first cell structure in a first direction that is parallel with the upper surface of the substrate;
a cell boundary between the first cell structure and the second cell structure in the first direction;
a first transistor crossing the cell boundary in the first direction and extending into the first cell structure and the second cell structure; and
a second transistor in at least one of the first cell structure and the second cell structure,
wherein the first transistor comprises a first sidewall and a second sidewall that is opposite to the first sidewall in the first direction,
wherein the second transistor comprises a third sidewall and a fourth sidewall that is opposite to the third sidewall in the first direction between the upper surface of the substrate and the first transistor in a second direction that is perpendicular to the upper surface of the substrate, and
wherein one of the third sidewall and the fourth sidewall overlaps the first transistor in the second direction.

8. The integrated circuit device of claim 7, wherein the first transistor has a first cell width in the first direction,
wherein the second transistor has a second cell width in the first direction, and
wherein the first cell width is equal to or greater than the second cell width.

9. The integrated circuit device of claim 8, wherein the first transistor further comprises a first channel layer that has a first channel width in the first direction,
wherein the second transistor further comprises a second channel layer that has a second channel width in the first direction, and
wherein the first channel width is equal to or greater than the second channel width.

10. The integrated circuit device of claim 9, wherein the second transistor crosses the cell boundary and extends into the first cell structure and the second cell structure.

11. The integrated circuit device of claim 7, wherein the first transistor is a P-type transistor, and the second transistor is an N-type transistor.

12. The integrated circuit device of claim 7, wherein the first transistor is an N-type transistor, and the second transistor is a P-type transistor.

13. The integrated circuit device of claim 7, wherein another one of the third sidewall and the fourth sidewall is free of overlap with the first transistor in the second direction.

14. An integrated circuit device comprising:
a substrate;
a first cell structure on an upper surface of the substrate;
a second cell structure that is adjacent the first cell structure in a first direction that is parallel with the upper surface of the substrate;
a cell boundary between the first cell structure and the second cell structure in the first direction;
a first transistor in at least one of the first cell structure and the second cell structure; and
a second transistor crossing the cell boundary in the first direction and extending into the first cell structure and the second cell structure,
wherein the first transistor comprises a first sidewall and a second sidewall that is opposite to the first sidewall in the first direction,
wherein the second transistor comprises a third sidewall and a fourth sidewall that is opposite to the third sidewall in the first direction between the upper surface of the substrate and the first transistor in a second direction that is perpendicular to the upper surface of the substrate, and
wherein one of the third sidewall and the fourth sidewall overlaps the first transistor in the second direction.

15. The integrated circuit device of claim 14, wherein the first transistor has a first cell width in the first direction,
wherein the second transistor has a second cell width in the first direction, and
wherein the second cell width is equal to or greater than the first cell width.

16. The integrated circuit device of claim 15, wherein the first transistor further comprises a first channel layer that has a first channel width in the first direction,
wherein the second transistor further comprises a second channel layer that has a second channel width in the first direction, and
wherein the second channel width is equal to or greater than the first channel width.

17. The integrated circuit device of claim 16, wherein the first transistor crosses the cell boundary and extends into the first cell structure and the second cell structure.

18. The integrated circuit device of claim 14, wherein the first transistor is a P-type transistor, and the second transistor is an N-type transistor.

19. The integrated circuit device of claim 14, wherein the first transistor is an N-type transistor, and the second transistor is a P-type transistor.

20. The integrated circuit device of claim 14, wherein another one of the third sidewall and the fourth sidewall is free of overlap with the first transistor in the second direction.
